(19) United States
(12) Patent Application Publication
(10) Pub. No.: US 2007/0257326 A1
(43) Pub. Date: Nov. 8, 2007

(54) INTEGRATED CIRCUIT STRUCTURE AND METHOD OF MANUFACTURING A MEMORY CELL

(76) Inventor: Chien-Li Kuo, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 11/382,061

(22) Filed: May 8, 2006

(51) Int. Cl. H01L 29/76; H01L 29/94; H01L 31/00; H01L 21/331

(52) U.S. Cl. 257/409; 438/343

(57) ABSTRACT

An integrated circuit structure is formed on a substrate. The integrated circuit structure includes a logic area and a memory cell area. The memory cell area includes a charge storage area and a non-charge storage area. A dielectric layer is formed on the substrate in the charge storage area. A thyristor is formed on the dielectric layer. A transistor is formed on the substrate in the non-charge storage area.

### BACKGROUND OF THE INVENTION

1. Field of the Invention

The present invention relates to a method of manufacturing a memory cell, and more particular, to a method of manufacturing a thyristor-based random access memory (T-RAM).

2. Description of the Prior Art

Thyristors are switching applications and have four layers, P₁-N₁-P₂-N₂, and three P-N junctions in series. An electrode defined as an anode is coupled to the external P₁ layer. An electrode defined as a cathode is coupled to the external N₂ layer. A gate electrode is coupled to the middle P₂ layer. A thyristor having this structure is called a silicon-controlled rectifier (SCR).

A characteristic of the thyristor is that the middle junction is reverse biased when positive voltage is added into the anode and passive voltage is added into the cathode, so there is no electrical current passing through the thyristor. However, when the positive voltage is added into the gate, the thyristor enters breakdown. The voltage of breakdown is the breakover voltage. When the voltage is bigger than the breakover voltage, the electrical current crosses the junction from the cathode to the anode, and the electrical current is called a holding current. When the thyristor is in breakdown, the gate is not controlled by the thyristor and the electrical current is maintained until the circuit breaks off or the voltage becomes zero, and the electrical current stops. So, the thyristor has a characteristic of holding voltage.

Additionally, thyristors also are bipolar devices, having characteristics of bisable and negative differential resistance (NDR).

Furthermore, the thyristors are bipolar devices and have characteristics of bistable and negative differential resistance (NDR), so they also apply to static random access memories (SRAMs) called T-RAM.

U.S. Pat. No. 6,528,356 discloses a method of manufacturing T-RAM. The T-RAM includes a vertical thyristor and a metal oxide semiconductor (MOS). The vertical thyristor is a thyristor having a structure of P1-N1-P2-N2 stacked from bottom to top. Even this T-RAM has advantages of stable electrical current and higher thermal stability. But, formation of the vertical thyristor needs several processes of poly silicon deposition; so integrating vertical thyristors utilizing the current CMOS processes is not easy. Besides, more processes are needed to complete the manufacture of the vertical thyristor.

On the other hand, to manufacture a planar P1N1P2N2 junction thyristor does not require additional diffusion or deposition processes. But, the planar thyristor needs to be deposited on a substrate of silicon on insulator (SOI) to avoid current leakage and to maintain the holding voltage. However, current manufacturing of the complementary metal-oxide semiconductor (CMOS) utilizes a silicon substrate, not SOI. So, the manufacture of T-RAM in the prior art cannot be combined with the current manufacturing of CMOS.

Therefore, to research a method of manufacturing a T-RAM utilizing the current manufacturing of CMOS is an important issue.

### SUMMARY OF THE INVENTION

It is therefore on object of the present invention to provide an integrated circuit structure to solve the problems of the prior art.

The claimed invention discloses an integrated circuit on a substrate. The integrated circuit structure defines a logic area and a memory cell area. The memory cell area includes a charge storage region and a no charge storage region. The charge storage region has an insulating layer in the substrate, and the insulating layer has a thyristor. The no charge storage region has a transistor on the substrate.

The claimed invention discloses a method of manufacturing a memory cell. A substrate is provided. The substrate defines a charge storage region and a no charge storage region. A shallow trench isolation (STI) region is formed in the substrate of the charge storage region and an insulating layer is formed on the STI region and the substrate of the no charge storage region. A thyristor is formed on the STI and a transistor in the no charge storage region.

In the claimed invention, the planar thyristor is formed on the silicon substrate, which is widely utilized in the current CMOS manufacturing process. Therefore, the claimed invention can apply to the current CMOS manufacturing process. Furthermore, because the transistor in the no charge storage region does not have the STI, the transistor still avoids current leakage.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1 to 5 are schematic diagrams of manufacturing processes according to the claimed invention.

### DETAILED DESCRIPTION

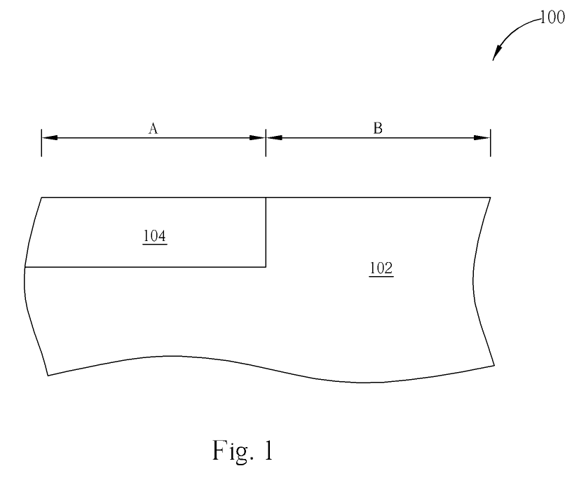

Please refer to FIGS. 1 to 5. FIGS. 1 to 5 are schematic diagrams of a manufacturing process according to the present invention. As FIG. 1 shows, the integrated circuit of the present invention is formed on a semiconductor wafer 100. The semiconductor wafer 100 includes a silicon substrate 102, and the silicon substrate 102 defines a charge storage region A and a no charge storage region B. The charge storage region A further comprises a shallow trench isolation (STI) region 104. In the current technology, forming the STI region 104 includes forming a patterned hard mask layer (not shown) on the silicon substrate 100, for example, stacked layers having pad oxide and silicon nitride, and then performing an etching process on the surface of the silicon substrate 102 without the hard mask to form a trench (not shown). Next, performing a spin on glass (SOG) process, a chemical vapor deposition (CVD) process filling in a dielectric material, for example, silicon oxide, and performing a chemical mechanical polishing (CMP) process to remove spare dielectric material nearly complete the process with the silicon oxide in the trench being the STI region 104. Finally, the patterned hard mask layer is removed.

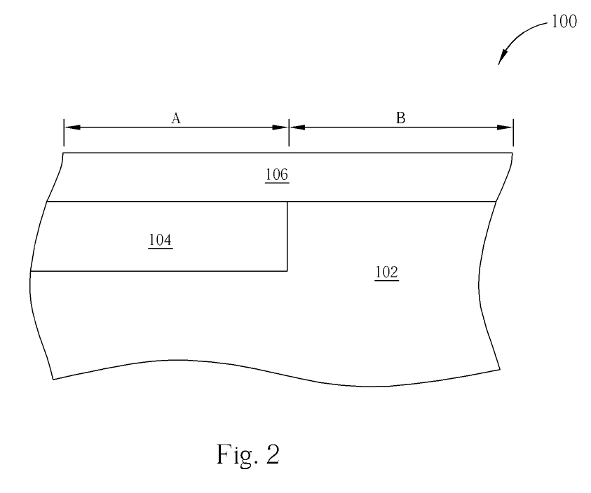

Please refer to FIG. 2. After completing the STI region 104, a silicon layer 106 is formed on the STI region 104 and the surface of the substrate 102 in the no charge storage region B by a low-pressure chemical vapor deposition (LPCVD) process. Then, according to demands of the manufacturer and product, an ion implantation process forms a implanting well of the semiconductor wafer 100 in the silicon layer 106 and the silicon substrate 102. In this embodiment, the implanting well in the silicon layer 106 and the silicon substrate 102 is a P type implanting well.

Please notice that the silicon layer 106 can be formed by an epitaxial growth method. On the other hand, the semiconductor wafer 100 completed with the STI region 104 can be put into a reaction apparatus (not shown) and increased in temperature to 1200 degrees centigrade with the reaction gas flowing into the reaction apparatus to form the silicon layer 106 on the surface of the STI region 104 in the charge storage region A and the surface of the silicon substrate 102 in the no charge storage region B. Subsequently, an ion implanting process forms an implanting well in the silicon layer 106 and the silicon substrate 102. It may be possible to omit the ion implanting process for forming the implanting well, since when forming the silicon layer 106, deposited or grown silicon having dopants can be used to form the silicon layer 106. So, the silicon layer 106 formed by the above-mentioned process is an implanting layer.

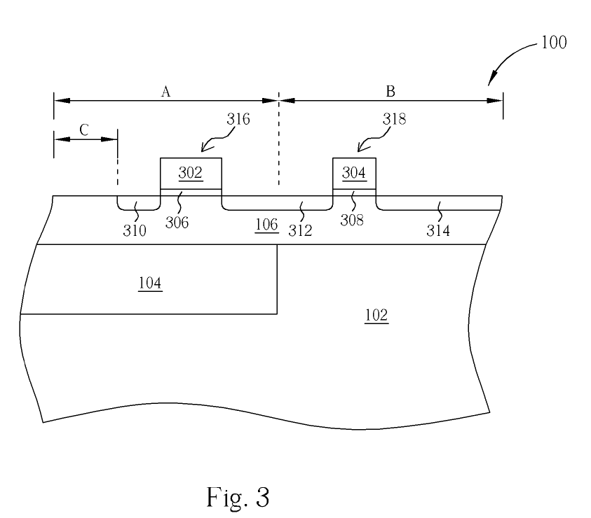

Please refer to FIG. 3. A dielectric layer (not shown) and a cap implanting poly-silicon layer (not shown) are formed on the silicon layer 106. Next, an etching process is processed to form gates 316, 318 respectively in the charge storage region A and the no charge storage region B. The dielectric layer is etched to form gate insulating layers 306, 308, and the implanting poly-silicon layers 302, 304 deposited on the gate insulating layers 306, 308. In this embodiment, the gate 316 is the gate of the thyristor, and the gate 318 is the gate of the transistor.

To manufacture the P₁N₁P₂N₂ junction of the thyristor, the charge storage region A defines a preserving region C, which is the position of the P₁ layer (anode) of the thyristor. Depositing a mask layer or a photo resist layer covers the preserving region C and performing an ion implanting process forms lightly doped drains (LDDs) 310, 312, and 314 at the two sides of the gates 316, 318 of the silicon layer 106.

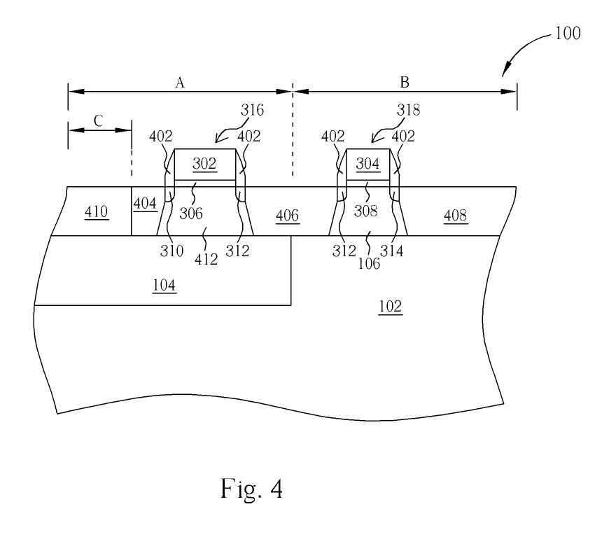

Please refer to FIG. 4. A uniform nitride silicon (SiN) layer (not shown) is formed on the surface of the semiconductor wafer 100 to cover the silicon layer 106 and the gates 316, 318. Next, an anisotropic dry etching process is performed to etch back the nitride silicon layer (not shown) and to form spacers 402. Subsequently, a mask layer or a photo resist layer is used to cover the preserving region C and an ion implanting process is performed to form implanting regions 404, 406, 408. Since the implanting regions 404, 406, 408 are N type implanting regions, the P type silicon layer 106 forms P type implanting regions 410, 412 between the N type implanting regions 404, 406.

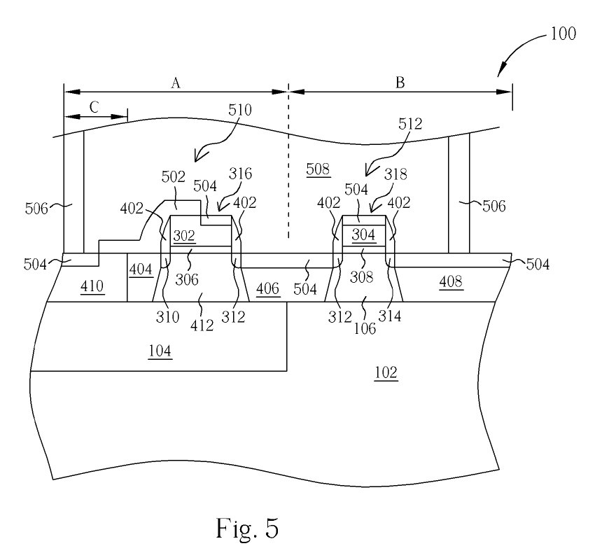

Please refer to FIG. 5. A salicide block (SAB) 502 is formed by a deposition process and an etching process on the partial gate 316, the implanting region 404, and the partial implanting region 410. Next, a salicide process is processed to form salicides on the gate 316 without the silicide block, the implanting region 410, the gate 318, and the implanting regions 406, 408. The gates 316 and the planar P type implanting region 410, N type implanting region 404, P type implanting region 412, and N type implanting region 406 form a thyristor 510, where the P type implanting region 410 is anode and the N type implanting region 406 is cathode. The gate 318 and the implanting regions 406, 408 form an N type transistor 512. A dielectric layer 508 is formed on the semiconductor wafer 100. Furthermore, each contact plug is formed to connect electrically the multilevel interconnects to complete the whole manufacture of the integrated circuit.

According to the above-mentioned manufacturing method, the present invention discloses a structure for an integrated circuit. It includes a thyristor 510 formed on the STI region 104 of the substrate 102 and a transistor 512 on the substrate 102. The thyristor 512 includes a gate 316 and the plane P type implanting region 410, N type implanting region 404, P type implanting region 412, and N type implanting region 406. The transistor 512 includes the gate 318 and the implanting regions 406, 408 as drain/source respectively. The N type implanting region 406 of the thyristor 510 is the drain/source of the transistor 512.

The integrated circuit of the present invention can be applied to a memory. In general, the memory includes a logic area and a memory cell. To take the above-mentioned example, the memory cell of the present invention includes a charge storage region A and a no charge storage region B. The charge storage region A has a thyristor 510 and the no charge storage region B has a transistor 512. Because the charge storage region A of the present invention has the thyristor 510 and the thyristor 510 is one part of the memory cell of the memory, the present invention completes a T-RAM. Furthermore, the manufacturing process of the thyristor 510 of the present invention is completed with the transistor, so the manufacturing process of the present invention is compatible with the current CMOS manufacturing process.

Please notice, in modifications of the present invention, the silicon layer or the silicon substrate of the present invention is the N type implanting region, and the LDDs 310, 312, 314 and the implanting regions 404, 406, 408 are the P type implanting regions.

In the prior art, a T-RAM having a planar thyristor is disposed on an SOI, but the SOI is not applicable with the current CMOS manufacturing process. So, the prior art is incompatible with the current CMOS manufacturing process. But in the present invention, the planar thyristor is formed on a silicon substrate, which is widely utilized in the current CMOS manufacturing process. The manufacturing process forms an STI region on the charge storage region of the substrate first. Next, the transistor and the thyristor are formed at the same time to complete the T-RAM of the present invention. To sum the above-mentioned processes, the present invention can be practiced with the current CMOS manufacturing process. Furthermore, because the transistor in the no charge storage region does not have the STI region, the transistor still reduces current leakage.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An integrated circuit structure on a substrate, the substrate defining a logic area and a memory cell area, a silicon layer being formed on the substrate, the memory cell area comprising:
a charge storage region having an insulating layer in the substrate of the charge storage region, the insulating layer having a thyristor, the thyristor partially being in the silicon layer; and
a no charge storage region having a transistor on the silicon layer.

2. The integrated circuit of claim 1 wherein the integrated circuit is a memory.

3. The integrated circuit of claim 1 wherein the insulating layer is a shallow trench isolation region.

4. The integrated circuit of claim 3 wherein the thyristor comprises:
a first gate in the silicon layer;
two P type implanting regions, two N type implanting regions being planar and interlaced each other to form a PNPN structure in the silicon layer.

5. The integrated circuit of claim 3 wherein the thyristor is a metal oxide semiconductor transistor.

6. The integrated circuit of claim 5 wherein the metal oxide semiconductor transistor comprises:
a gate in the silicon layer; and
a drain/source in the silicon layer.

7. A method of manufacturing a memory cell, comprising:
providing a substrate, the substrate defining a charge storage region and a no charge storage region;
forming a shallow trench isolation (STI) region in the substrate of the charge storage region;
forming a silicon layer on the STI region and the substrate of the no charge storage region; and
forming a thyristor on the STI region of the charge storage region and a transistor in the no charge storage region.

8. The method of claim 7 wherein the silicon layer is an implanting silicon layer.

9. The method of claim 7 further comprising performing a first ion implanting process to form an implanting well in the substrate and the silicon layer after the silicon layer is completed.

10. The method of claim 7 wherein the steps of forming the thyristor and the transistor further comprise:
forming two gates individually in the charge storage region and the no charge storage region on the silicon layer;
performing a second ion implanting process to form a plurality of lightly doped drains (LDDs) at two sides of the gates and in the silicon layer; and
performing a third ion implanting process to form a plurality of implanting regions at the two sides of the gates and in the silicon layer.

11. The method of claim 10 wherein the charge storage region further comprises a preserving region, when the second ion implanting process is performed, the preserving region is covered with a first mask.

12. The method of claim 11 further comprising covering the preserving region with a second mask before the third ion implanting process is performed.

13. The method of claim 10 further comprising the following steps after the implanting regions are formed:
forming a salicide block on part of the gate and part of the silicon layer of the charge storage region; and
performing a salicide process to form a plurality of salicidies on the implanting regions and the gates without the salicide block.

14. The method of claim 10, wherein the memory cell applies to a T-RAM.
